(19) United States
(12) Patent Application Publication
(10) Pub. No.: US 2015/0099371 A1
(43) Pub. Date: Apr. 9, 2015

(54) NOZZLE DESIGNS FOR DISTRIBUTION OF REACTANTS ACROSS SUBSTRATES

(71) Applicant: QUALCOMM MEMS TECHNOLOGIES, INC., San Diego, CA (US)

(72) Inventors: Ana R. Londergan, Santa Clara, CA (US); Sandeep K. Giri, Sunnyvale, CA (US); Teruo Sasagawa, Los Gatos, CA (US); Shih-chou Chiang, Taoyuan City (TW); Tsutomu Satoyoshi, Tokyo (JP); Tanaka Seiji, Tokyo (JP)

(73) Assignee: QUALCOMM MEMS TECHNOLOGIES, INC., San Diego, CA (US)

(21) Appl. No.: 14/045,734

(22) Filed: Oct. 3, 2013

(51) Int. Cl. H01L 21/02; H01L 21/67

(52) U.S. Cl. CPC H01L 21/0228; H01L 21/67017
USPC 438/758; 118/715

(57) ABSTRACT

Systems, methods and apparatus for processing a substrate are described. A reactor includes a reaction chamber, a composite nozzle, and a reaction chamber outlet. The composite nozzle extends along a side of the chamber and includes a first nozzle and a second nozzle separate from and parallel the first nozzle. Each nozzle includes a body extending along an axis of elongation, an inlet providing communication between at least one source of a common species and an inner volume of the body, and holes spaced along the axis. The holes provide fluid communication between the inner volume and the chamber. The outlet is configured to allow flow from the composite nozzle through the chamber to the outlet. The first nozzle inlet is positioned at a first end of the first body, and the second nozzle inlet is positioned at a second end of the second body. The second end is opposite the first end of the first body.

### TECHNICAL FIELD

This disclosure relates to equipment and methods for processing substrates.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can include microelectromechanical systems (MEMS) devices with structures having sizes ranging from about a micron to hundreds of microns or more, or nanoelectromechanical systems (NEMS) devices with structures having sizes smaller than a micron including, for example, sizes smaller than several hundred nanometers, or other scales. Electromechanical elements may be created using deposition, etching, lithography, and/or other micromachining processes that etch away parts of substrates and/or deposited material layers, or that add layers to form electrical and electromechanical devices. One type of EMS device is called an interferometric modulator (IMOD), or interferometric light modulator, which refers to a device that selectively absorbs and/or reflects light using the principles of optical interference. An IMOD display element may include a pair of conductive plates, one or both of which may be transparent and/or reflective, wholly or in part, and capable of relative motion upon application of an appropriate electrical signal. The position of one plate in relation to another can change the optical interference of light incident on the IMOD display element. IMOD-based display devices have a wide range of applications, and are anticipated to be used in improving existing products and creating new products, especially those with display capabilities.

The aforementioned electromechanical systems devices can be fabricated using various processing tools and systems. Conventional semiconductor fabrication equipment, such as atomic layer deposition (ALD) and chemical vapor deposition (CVD), have been adapted for fabricating display panels. However, new challenges are being found in obtaining the desired uniformity for large rectangular substrates often used to form displays. Such substrates can be employed for MEMS displays, such as the IMOD display technology described above, as well as other display technologies, such as LCD, LED, OLED, etc. Equipment designs optimized for smaller, radially symmetric substrates, such as silicon wafers, are not readily adapted to these larger substrates of different shapes.

### SUMMARY

The systems, methods and devices of this disclosure each have several innovative aspects, no single one of which is solely responsible for the desirable attributes disclosed herein.

One innovative aspect of the subject matter described in this disclosure can be implemented in a reactor for processing a substrate. The reactor includes a reaction chamber configured to process a single substrate. The reactor includes a substrate support configured to support a single substrate within the reaction chamber. The reactor includes a composite nozzle extending along a side of the reaction chamber. The composite nozzle includes a first nozzle and a second nozzle separate from and positioned parallel the first nozzle. Each nozzle includes a nozzle body forming an inner volume, the nozzle body extending along an axis of elongation. Each nozzle includes an inlet providing fluid communication between at least one source of a common reactant source species and the inner volume. Each nozzle includes a plurality of holes spaced along the axis of elongation of the nozzle body, the holes providing fluid communication between the inner volume of the nozzle body and the reaction chamber. The reactor includes a reaction chamber outlet positioned and configured to allow flow from the composite nozzle through the reaction chamber to the reaction chamber outlet, wherein the flow is parallel to a major surface of the substrate. The inlet of the first nozzle is positioned at a first end of the nozzle body of the first nozzle. The inlet of the second nozzle is positioned at a second end of the nozzle body of the second nozzle, where the second end is opposite to the first end of the nozzle body of the first nozzle.

In some implementations, the composite nozzle is configured to present a back-pressure of less than 5 Torr to gases. In some implementations, the reactor includes separate ones of the composite nozzle. In some implementations, the first and second nozzle of each composite nozzle are stacked vertically adjacent to each other.

Another innovative aspect of the subject matter described in this disclosure can be implemented in a reactor for processing a substrate. The reactor includes a reaction chamber configured to process a single substrate having a surface. The reactor includes a means for supporting a substrate within the reaction chamber. The reactor includes a means for introducing a reactant into the reaction chamber parallel to the substrate surface. The reactant introducing means includes a first means for injecting the reactant into the reaction chamber with a first decreasing gradient of volumetric flow rates extending parallel to an edge of the substrate. The reactant introducing means includes a second means for injecting the reactant into the reaction chamber with a second decreasing gradient of volumetric flow rates extending parallel to the edge of the substrate and opposite to the first gradient, to compensate for the first gradient.

In some implementations, the first reactant injecting means includes a first nozzle tube and a first inlet positioned at a first end of the first nozzle tube, and the second reactant injecting means includes a second nozzle tube and a second inlet positioned at a second end of the second nozzle tube that is opposite to the first end of the first nozzle tube, the second nozzle tube approximately parallel to the first nozzle tube. In some implementations, the reactor includes at least two reactant introducing means stacked vertically adjacent with respect to each other. In some implementations, the reactor further includes a nozzle outlet positioned at second ends of each nozzle tube, the second ends being opposite the first ends, wherein each nozzle outlet is in selective communication with a vacuum supply. In some implementations, the reactant introducing means is configured to present a back-pressure of less than 5 Torr to gases. In some implementations, the reactor includes separate ones of the reactant introducing means.

Another innovative aspect of the subject matter described in this disclosure can be implemented in a method of processing a substrate in a single substrate reaction chamber. The method includes distributing a reactant within a composite nozzle elongated along an edge of the substrate. Distributing includes distributing the reactant from a first nozzle inlet in a first direction along a first nozzle tube elongated along the edge of the substrate. Distributing further includes distributing the reactant from a second nozzle inlet along a second nozzle tube elongated along the edge of the substrate, in a second direction opposite to the first direction. The method includes injecting reactant from openings along the first and second elongated nozzle tubes into the reaction chamber. The method includes flowing the reactant from the openings through the reaction chamber to a reaction chamber outlet, wherein the flow is parallel to a major surface of the substrate.

In some implementations, injecting reactant includes presenting a back-pressure of less than 5 Torr to gases. In some implementations, the method including repeating the method within the single substrate reaction chamber, with a separate reactant, within a separate composite nozzle with separate nozzle inlets and separate nozzle tubes, with separate openings. In some implementations, flowing the reactant from the openings includes flowing reactant from adjacent first and second nozzle tubes corresponding to the same composite nozzle. In some implementations, flowing the reactant includes flowing the reactant to the reaction chamber outlet positioned on an opposite side of the substrate relative to the common edge of the substrate. In some implementations, the method includes one of the first nozzle tube or the second nozzle tube, or both, from a nozzle outlet positioned at an end of the nozzle tube opposite to the nozzle inlet.

In some implementations, the reaction chamber is configured to process rectangular substrates having an area greater than the area of rectangular substrate with dimensions of about 700 mm by about 900 mm.

Details of one or more implementations of the subject matter described in this disclosure are set forth in the accompanying drawings and the description below. Although the examples provided in this disclosure are primarily described in terms of EMS and MEMS-based displays the concepts provided herein may apply to equipment and methods for manufacturing other types of displays such as liquid crystal displays, organic light-emitting diode (“OLED”) displays, and field emission displays. Additionally, the concepts provided herein may apply to other types of devices formed on substrates, such as semiconductor and integrated circuits. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is a flow diagram illustrating a manufacturing process for an IMOD display or display element.

FIGS. 2A-2F are cross-sectional illustrations of various stages in a process of making an IMOD display or display element.

FIG. 3 is an example of a schematic plan view of a reactor for processing a substrate, in accordance with one implementation.

FIG. 4 is a cross-sectional view of the reactor for processing a substrate in FIG. 3, showing a front elevational view of a composite nozzle in accordance with an implementation.

FIG. 5 is a cross-sectional view of a reactor for processing a substrate, showing a front elevational view of two stacked composite nozzles, in accordance with an implementation.

FIG. 6 is an example of a system block diagram illustrating a reactor including a reaction chamber and a control system, in accordance with an implementation.

FIG. 7 is an example of a flow diagram illustrating a method of processing a substrate, in accordance with an implementation.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in apparatuses, systems, and processes to fabricate any device, apparatus, or system, such as those configured to display an image, whether in motion (such as video) or stationary (such as still images), and whether textual, graphical or pictorial. More particularly, it is contemplated that the described implementations may be associated with fabrication of a variety of electronic devices such as, but not limited to, electromechanical systems (EMS) applications including microelectromechanical systems (MEMS) applications, as well as non-EMS applications. The teachings herein also can be used in fabrication of non-display electronic devices. Thus, the teachings are not intended to be limited to the implementations depicted solely in the Figures, but instead have wide applicability as will be readily apparent to one having ordinary skill in the art.

A reactor for processing a substrate is disclosed that can be used to fabricate a device (e.g., a MEMS or integrated circuit device). The reactor can include a substrate support for supporting a substrate within a reaction chamber, and in some implementations, a single substrate. A composite nozzle extending along a side of the reaction chamber can include a first nozzle, and a second nozzle separate from and positioned parallel the first nozzle. As used herein with respect to the positioning of nozzles or composite nozzles, “separate” is defined as the ability of each component to have a separate flowpath within its inner volume; the nozzles or composite nozzles can be physically contacting each other, or separated by a gap. Additionally, as used herein “parallel” should not be defined as being “straight” but is defined as the relative equidistant positioning between two axes, even if the axes are curvilinear, or structures that are defined relative to these axes.

The first and second nozzles can each include an inlet, through which a common reactant is introduced into the reaction chamber from a plurality of holes spaced along a body of each nozzle. The inlet of the first nozzle can be positioned at a first end of the nozzle body of the first nozzle, and the inlet of the second nozzle can be positioned at a second end of the nozzle body of the second nozzle. The inlets can be at opposite ends of first and second nozzles.

Particular implementations of the subject matter described in this disclosure can be implemented to realize one or more of the following potential advantages. Reducing back-pressure within a vapor reactant nozzle (e.g., to 0.5 to 5 Torr), can be advantageous for reducing particle generation for some processes, such as atomic layer deposition (ALD). However, reduced back-pressure can also reduce flow uniformity of reactant across the substrate, and this problem can be exacerbated as substrate sizes are scaled up. Such uniformity was not perceived as being an issue for a self-limiting, saturative process, such as ALD, but has become an issue with large-format substrates. While MEMS devices have traditionally been manufactured on small-format substrates, to increase throughput and reduce cost, it would be beneficial to manufacture MEMS devices on large-format substrates. To improve ALD for the fabrication of MEMS devices using large-format substrates will require improved flow uniformity of reactant across the length of the nozzle and the substrate. A reaction chamber composite nozzle with first and second nozzles that have opposed inlets and flow directions can improve reactant uniformity, and compensate for pressure drop along the length of the composite nozzle.

Implementations can be applied, for example, to manufacturing display devices and/or EMS devices. An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

In some single substrate reactors, the reactant distribution systems (e.g., showerheads or other nozzles) tend to rely on a high back-pressure behind nozzle injectors to improve uniformity of reactant distribution, and to increase film growth speed (to avoid the reduction in throughput of a single wafer system). However, high back-pressure with nozzle injection can increase particle generation, and thus reduce film and deposition quality. For example, in atomic layer deposition, high back-pressure can cause some amount of residual reactant to continue bleeding into the reactor from the nozzle after the first reactant is pulsed, and even during the second reactant pulse. This can result in gas phase interaction between mutually reactive ALD reactants and particulate formation, which can reduce quality of the devices being manufactured. Clearing (e.g., purging) the nozzles of reactants between pulse steps can reduce this particle formation, but high back-pressure can lengthen the time it takes for such purging steps.

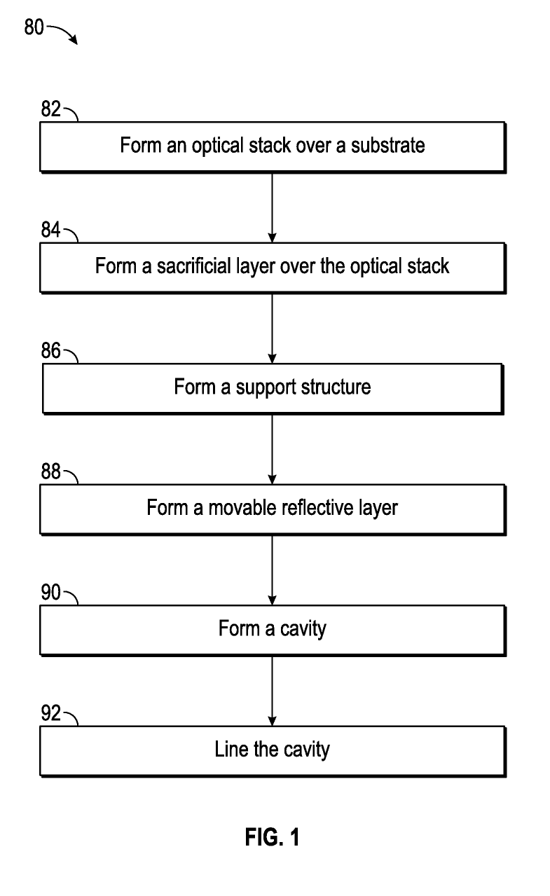

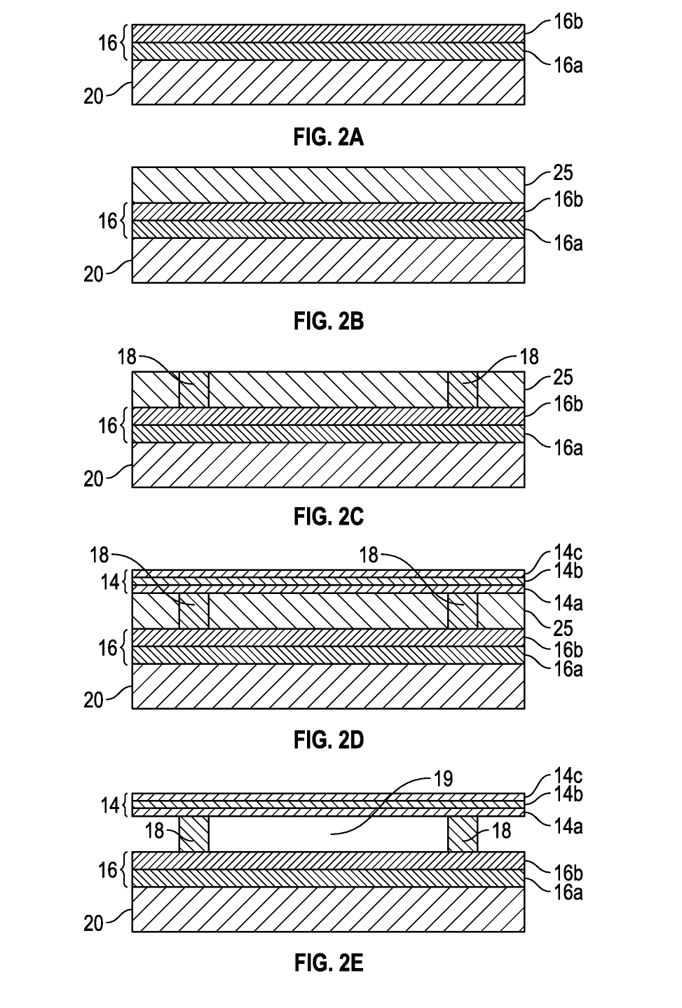

FIG. 1 is a flow diagram illustrating a manufacturing process 80 for an IMOD display or display element. FIGS. 2A-2F are cross-sectional illustrations of various stages in a manufacturing process 80 for making an IMOD display or display element. In some implementations, the manufacturing process 80 can be implemented to manufacture arrays of EMS devices, such as IMOD displays. The manufacture of such an EMS device also can omit some illustrated blocks and/or include other blocks not shown in FIG. 1. The process 80 begins at block 82 with the formation of an optical stack 16 over a substrate 20. FIG. 2A illustrates such an optical stack 16 formed over the substrate 20. The substrate 20 may be a substrate such as a glass substrate (sometimes referred to as a workpiece, glass plate or panel). Example substrates include standard rectangular formats, including G1 (˜300 mm×350 mm); G2 (˜370 mm×470 mm); G3 (˜550 mm×650 mm); G4 (˜730 mm×920 mm); G5 (˜1100 mm×1250 mm); G6 (˜1500 mm×1850 mm); G7 (˜1950 mm×2200 mm); G8 (˜2200 mm×2400 mm); G10 (2880 mm×3130 mm); In some implementations, the glass substrate may have a thickness of 0.3, 0.5 or 0.7 millimeters, although in some implementations the glass substrate can be thicker (such as tens of millimeters) or thinner (such as less than 0.3 millimeters).

The glass substrate may be or include, for example, aluminum silicate glass, a borosilicate glass, a soda lime glass, quartz, Pyrex, or other suitable glass material. In some implementations, a non-glass substrate can be used, such as a polyimide, polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. In some implementations, the substrate may be or include silicon, or other materials used in IC manufacturing. The substrate 20 may be flexible or relatively stiff and unbending, and may have been subjected to prior preparation processes, such as cleaning, to facilitate efficient formation of the optical stack 16. The optical stack 16 can include an electrically conductive layer, and can be partially transparent, partially reflective and partially absorptive, and may be fabricated, for example, by depositing one or more layers having the desired properties onto the transparent substrate 20.

In FIG. 2A, the optical stack 16 includes a multilayer structure having sub-layers 16a and 16b, although more or fewer sub-layers may be included in some other implementations. In some implementations, one of the sub-layers 16a and 16b can be configured with both optically absorptive and electrically conductive properties, such as a combined conductor/absorber sub-layer 16a. In some implementations, one of the sub-layers 16a and 16b can include a semireflective thickness of a metallic material, such as molybdenum-chromium (molychrome or MoCr), or other materials with a suitable complex refractive index. Additionally, one or more of the sub-layers 16a and 16b can be patterned into parallel strips, and may form row electrodes in a display device. Such patterning can be performed by a masking and etching process or another suitable process known in the art. In some implementations, one of the sub-layers 16a and 16b can be an insulating or dielectric layer, such as an upper sub-layer 16b that is deposited over one or more underlying metal and/or oxide layers (such as one or more reflective and/or conductive layers). In addition, the optical stack 16 can be patterned into individual and parallel strips that form row electrodes of the display. In some implementations, at least one of the sub-layers of the optical stack, such as the optically absorptive layer, may be quite thin (for example, relative to other layers depicted in this disclosure), even though the sub-layers 16a and 16b are shown somewhat thick in FIGS. 2A-2F.

The process 80 continues at block 84 with the formation of a sacrificial layer 25 over the optical stack 16. Because the sacrificial layer 25 is later removed (see block 90) to form a cavity 19 (see FIG. 2E), the sacrificial layer 25 is not present in the resulting IMOD display elements. FIG. 2B illustrates a partially fabricated device including a sacrificial layer 25 formed over the optical stack 16. The formation of the sacrificial layer 25 over the optical stack 16 may include deposition of a fluorine-etchable material such as molybdenum (Mo) or amorphous silicon (Si), in a thickness selected to provide, after subsequent removal, a gap or cavity 19 (see FIG. 2E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating.

The process 80 continues at block 86 with the formation of a support structure such as a support post 18. The formation of the support post 18 may include patterning the sacrificial layer 25 to form a support structure aperture, then depositing a material (such as a polymer or an inorganic material, like silicon oxide) into the aperture to form the support post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the support post 18 contacts the substrate 20. Alternatively, as depicted in FIG. 2C, the aperture formed in the sacrificial layer 25 can extend through the sacrificial layer 25, but not through the optical stack 16. For example, FIG. 2E illustrates the lower ends of the support posts 18 in contact with an upper surface of the optical stack 16. The support post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 2C, but also can extend at least partially over a portion of the sacrificial layer 25. Patterning can include photolithography to mask the post regions with mask features slightly wider than the apertures, and a selective etch process designed to stop on the sacrificial layer 25. As noted above, the patterning of the sacrificial layer 25 and/or the support posts 18 can be performed by a masking and etching process, but also may be performed by alternative patterning methods. Such patterning and its selective etching processes are examples of processes that may be performed with implementations of the plasma apparatus and methods described further herein.

The process 80 continues at block 88 with the formation of a movable reflective layer or membrane such as the movable reflective layer 14 illustrated in FIG. 2D. The movable reflective layer 14 may be formed by employing one or more deposition steps, including, for example, reflective layer (such as aluminum, aluminum alloy, or other reflective materials) deposition, along with one or more patterning, masking and/or etching steps. The movable reflective layer 14 can be patterned into individual and parallel strips that form, for example, column electrodes of the display that cross with the row electrode strips formed from the optical stack 16. The movable reflective layer 14 can be electrically conductive, and referred to as an electrically conductive layer. In some implementations, the movable reflective layer 14 may include a plurality of sub-layers 14a, 14b and 14c as shown in FIG. 2D. In some implementations, one or more of the sub-layers, such as sub-layers 14a and 14c, may include highly reflective sub-layers selected for their optical properties, and another sub-layer 14b may include a mechanical sub-layer selected for its mechanical properties. In some implementations, the mechanical sub-layer may include a dielectric material. Since the sacrificial layer 25 is still present in the partially fabricated IMOD display element formed at block 88, the movable reflective layer 14 is typically not movable at this stage. A partially fabricated IMOD display element that contains a sacrificial layer 25 also may be referred to herein as an “unreleased” IMOD.

The process 80 continues at block 90 with the formation of a cavity such as the cavity 19 of FIG. 2E. The cavity 19 (FIG. 2E) may be formed by exposing the sacrificial material 25 (deposited at block 84) to an etchant. For example, an etchable sacrificial material such as Mo or amorphous Si may be removed by dry chemical etching by exposing the sacrificial layer 25 to a gaseous or vaporous etchant, such as vapors derived from solid XeF₂ for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD display element may be referred to herein as a “released” IMOD.

The process 80 continues at block 92 with the lining of the cavity 19 with one or more layers as shown in FIG. 2F. For example, after release etching defines the cavity 19, at least the reflective layer 14a and top of the optical stack 16, and in the illustrated implementation all interior surfaces of the cavity 19, can be coated conformally with an antistiction layer 31. The illustrated conformal antistiction layer 31 includes a conformal layer 31a, which can be formed by atomic layer deposition (ALD), and a self-assembled monolayer (SAM) 31b as described below. In some implementations the conformal layer 31a can be an inorganic layer. In some implementations the conformal layer 31a can be a dielectric layer. It will be understood that antistiction properties can be obtained with one or both of the conformal layer 31a (formed, for example, by ALD) and the SAM 31b. For implementations in which both are employed, the conformal layer 31a can serve as a seed layer for forming the SAM thereover.

In some implementations, the packaging of a display, such as the IMOD-based display described above, can include a backplate (alternatively referred to as a backplane, back glass or recessed glass) which can be configured to protect the EMS components from damage (such as from mechanical interference or potentially damaging substances). The backplate also can provide structural support for a wide range of components, including but not limited to driver circuitry, processors, memory, interconnect arrays, vapor barriers, product housing, and the like. In some implementations, the use of a backplate can facilitate integration of components and thereby reduce the volume, weight, and/or manufacturing costs of a portable electronic device.

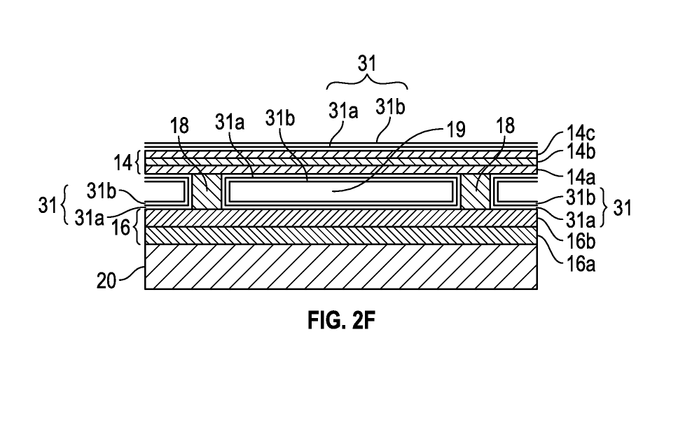

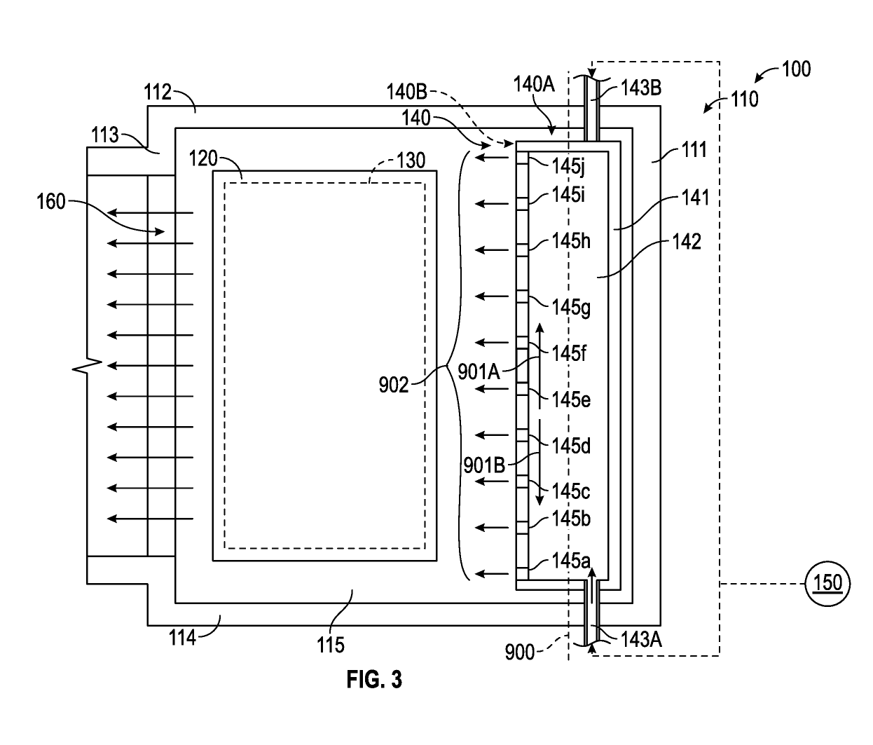

FIG. 3 is an example of a schematic plan view of a reactor for processing a substrate, in accordance with one implementation. FIG. 4 is a cross-sectional view of the reactor for processing a substrate in FIG. 3, showing a front elevational view of a composite nozzle in accordance with an implementation. Referring to FIGS. 3-4, a reactor 100 can include a reaction chamber 110 and a substrate support 120 configured (sized and shaped) to support a single workpiece or substrate 130 within the reaction chamber 110. For example, reaction chamber 110 and substrate support 120 can be configured sufficiently small enough such that only a single substrate can be processed therein, without use of a wafer boat or multiple-wafer substrate support. The reactor 100 can include a composite nozzle 140 which includes two or more nozzles or sections, such as nozzles 140A and 140B, best seen in the elevational view of FIG. 4. The composite nozzle 140 can be configured to fluidly communicate one or more gases from gas storage or generation equipment to the reaction chamber 110. Both nozzles 140A and 140B can each communicate with at least one source of the same reactant(s) or species, such that the same reactant or mixture of reactants are provided to both nozzles 140A and 140B. For example, as illustrated, the composite nozzle 140 can be configured to be in fluid communication with a common reactant source 150. In other arrangements, the different nozzles 140A and 140B can communicate with different reactant sources that house the same reactant or reactant mixture. The composite nozzle 140 is configured to receive a reactant from the (at least one) reactant source 150 and supply the reactant into the reaction chamber 110, to perform a process on the substrate 130.

In some implementations, reactor 100 can be configured for processes that use mixed reactants, such as CVD. Some CVD process use only one precursor, and so only one composite nozzle as described herein might be employed, e.g., depositing silane to form amorphous Si. Some CVD processes may include at least two reactants that are substantially non-reactive at the temperature of the composite nozzle (e.g., room temperature). Such processes can allow the at least two reactants to be mixed within a common gas line prior to entering the composite nozzle, and thus may be implemented with only one composite nozzle, both nozzles of which receive the same mixed reactant. Such processes may react the different reactants of the mixture at the higher temperature of the substrate, and/or react in the presence of a plasma inside the chamber.

Some CVD processes may include two or more reactants that are reactive within one another even at lower temperatures (such as room temperature). Such processes may include a first composite nozzle configured to inject a first reactant continuously during the deposition step, while a second composite nozzle injects a second reactant continuously. In some such CVD processes, a first composite nozzle may inject a first reactant through a first composite nozzle continuously during the deposition step, while a second composite nozzle pulses a second reactant. In some CVD processes, multi-component films may be deposited that could be provided with more than two composite nozzles and more than two composite reactants, such as a three reactant and three composite nozzle configuration to deposit an indium tin oxide film (mix of indium oxide and tin oxide), or even three or four composite nozzles for indium gallium zinc oxide (depending on how oxygen is introduced into the process). With an ALD process, a first reactant is pulsed through one or more composite nozzles, followed sequentially by a pulse of a second reactant through one or more additional composite nozzles. A gas control system, such as a gas panel, valving and/or other components for controlling fluid flow, can be included between the reactant source 150 and the composite nozzle 140 to control the flow of gases into nozzles 140A and 140B and/or other portions of reactor 100.

In some implementations, reactor 100 can be configured for ALD. With an ALD process, separate reactants can be provided through separate composite nozzles. For example, a first reactant is pulsed through a first composite nozzle, followed sequentially by a pulse of a second reactant through a second composite nozzle. In some arrangements, third, fourth, etc. composite nozzles can be provided for third, fourth, etc. ALD reactants. A gas control system, such as a gas panel, valving and/or other components for controlling fluid flow, can be included between the reactant source 150 and the corresponding composite nozzle 140 to control the flow of gases into composite nozzle 140 and/or other portions of reactor 100.

In some implementations, reactor 100 and the other reactors described herein can include two or more composite nozzles configured to fluidly communicate one or more gases to a reaction chamber. For example, two or more composite nozzles may be implemented to separately provide two or more reactants into a reaction chamber, either sequentially, or simultaneously. Each nozzle of a composite nozzle can be supplied with the same reactant (or same mixture of reactants in some cases). Each composite nozzle 140 can be in communication with one or more inert gas sources. For example, one or more inert gas sources can be configured to provide purge gas, and/or to act as a carrier for reactant, to the reaction chamber 110.

Multiple reactants can be provided to the same composite nozzle for both CVD (mixed or sequential, typically mixed) and ALD (sequentially). However, for ALD providing separate reactants with two or more separate composite nozzles may be employed to minimize risk of interaction of the reactants in the nozzle, such as residual first reactant from a first reactant pulse interacting with a subsequent second reactant pulse, thus minimizing risk of particulate generation from such interaction. For example, the reactant sources may include a vessel and/or vaporizer holding a metal reactant, such as trimethyl aluminum (TMA, (CH₃)₃Al) and another vessel and/or vaporizer for an oxygen source vapor, such as water, for the ALD deposition of aluminum oxide. Separate composite nozzles can be provided for each of these two different reactants to reduce the risk of reactions in the nozzle.

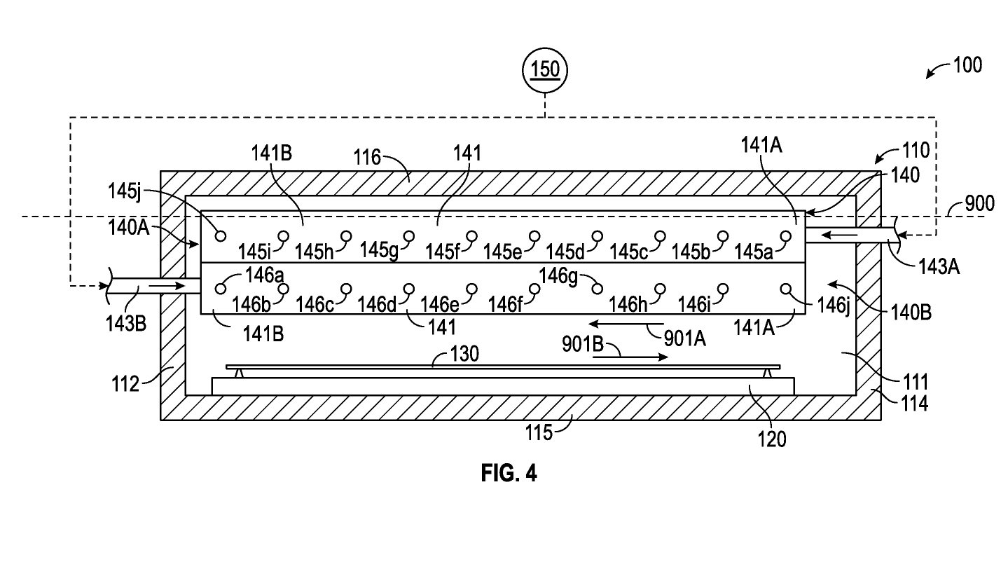

In operation, the TMA and water can be delivered to the reaction space by alternate and sequential pulses by high speed valves, with intervening removal of reactants from the composite nozzles and the reaction chamber, such as by providing an inert gas to purge the composite nozzles and reactor of the previous reactant. Removal of a first reactant from a first composite nozzle while a second reactant is supplied through a second composite nozzle reduces the risk of out-diffusion of the first reactant from the first composite nozzle while the second reactant is being supplied to the reaction chamber. As TMA is naturally liquid, the vessel can also serve as a vaporizer, such as a bubbler. The TMA can adsorb on surfaces of the batch of substrates in one reactant pulse, including inside the MEMS cavities in some implementations, and the water can react with the adsorbed species in a subsequent pulse to form a self-limited monolayer of aluminum oxide. Multiple cycles can be performed to form an aluminum oxide layer having a desired thickness, depending upon the average thickness per cycle (for example, from 0.5 Å/cycle to 10 Å/cycle). In some implementations, the aluminum oxide layer has a thickness of about 3 Å to about 50 Å. In some implementations, the aluminum oxide layer has a thickness of about 40 Å to about 90 Å. An example of an implementation of a reactor with two composite nozzles corresponding with two reactant sources is described further herein with reference to FIG. 5.

Referring to FIG. 3, the reactor 100 can include an outlet 160 configured to allow flow from the composite nozzle 140 through the reaction chamber 110, and to the outlet 160. The outlet 160 can include any of a number of different shapes suitable to exhaust the reaction chamber 110, such as one or more conduits, slots, openings, manifolds, etc. The outlet 160 can be configured to allow flow from the reaction chamber 110, for example, to allow continuous flow of reactant through the chamber during deposition and to purge the reaction chamber 110 after deposition or between ALD pulses through an exhaust system. The exhaust system can include any of a number of different components suitable to provide and/or control such exhaust, such as one or more vacuum pumps, valves, regulators, sensors (e.g., pressure sensors, temperature sensors, flow sensors, etc.), and other components, or combinations thereof. In general, the outlet 160 is positioned and its opening(s) are distributed on the opposite side of the reaction chamber 110 from the composite nozzle 140 such as to provide horizontal, laminar flow across the substrate support 120. For implementations in which nozzles are provided on multiple sides of the reaction chamber, multiple exhausts can be provided opposite each nozzle to provide a cross-flow path across the substrate.

Referring to FIGS. 3 and 4, the substrate 130 can be held or supported by the substrate support 120 using any of a number of different structures. The substrate support 120 can be configured to reduce contact between the substrate 130 and substrate support 120 to reduce contamination and/or damage to the substrate 130. For example, substrate support 120 may include an edge-grip susceptor, a recessed (concave) susceptor, and/or a plurality of support pins.

The reaction chamber 110 can be configured to receive substrates used to form electromechanical system devices and/or integrated circuit devices, such as glass, silicon, and the like. In an implementation, the reaction chamber 110 can be configured to process a rectangular glass substrate 130 ranging from an industry-standard display panel size G1 (300×350 mm) to G10 (2880×3130 mm). The reaction chamber 110 can process a substrate with a length that can range from about 350 mm to about 3130 mm, in one implementation; from about 470 mm to about 1850 mm, or from about 650 mm to about 1250 mm in another implementation. The reaction chamber 110 can process a substrate with a width that can range from about 300 mm to about 2880 mm in one implementation; from about 370 mm to about 1500 mm in another implementation; or from about 550 mm to about 1100 mm in another implementation. In one example, the substrate 130 can be a rectangular glass workpiece with a length×width of about 920 mm×730 mm. In some implementations, the reaction chamber 110 can be configured to process a substrate with dimensions that are greater than or equal to an industry-standard display panel size of G4, for example, between or including the industry-standard display sizes of G4 and G10. The reaction chamber can be configured to accommodate rectangular substrates with an area greater than about 700 mm by 900 mm.

The reaction chamber 110 can include sidewalls 111-114, as well as a base 115 and a top 116 (see FIG. 4). The side(s), base(s), and top(s) of the reaction chambers described herein form an interior volume. In some implementations, sidewalls 111 and 113 can be positioned on approximately opposed sides of the substrate 130 with respect to each other, when the substrate 130 is positioned on the substrate support 120. In some implementations, sidewalls 112 and 114 can be positioned on approximately opposed sides of the substrate 130 with respect to each other, when the substrate 130 is positioned on the substrate support 120. Sidewalls 112 and 114 can be adjacent and oriented orthogonally with respect to sidewalls 111 and 113.

The chamber 110 can include materials suitable for a substrate process, such as ALD and CVD. For example, the chamber 110 can include a metal and/or metal alloy such as aluminum, stainless steel, etc. Portions of the chamber exposed to reactants can be formed of a material resistant to the processing gas, to reduce corrosion that may be caused by the process. For example, in some implementations wherein the reactor 100 is configured as an ALD reactor, some portions of the reaction chamber 110 (within the ALD reaction space) can be made of a material that is resistant to TMA, water, reaction by-products and any cleaning etchants. Examples of suitable chamber materials include aluminum, aluminum alloy, anodized aluminum, SS304, SS316, quartz, or titanium and/or aluminum oxide. The surface of these materials may be treated, for example, through coatings (e.g., aluminum oxide or yttrium oxide), anodization or roughening (e.g., to prevent film peeling). The roughness can be 3 μm Ra. In some implementations the reaction space is periodically cleaned to remove aluminum oxide formed on the reaction space surfaces.

The reaction chamber 110 can be suitably configured to be sealed apart from the metered inlets and outlets, and held to a particular pressure during at least a portion of the process therein. In some implementations wherein the reactor 100 is configured as an ALD reactor, the pressure in the reaction space during the ALD process is from about 100 mTorr to about 1 Torr. Some implementations of the nozzles described herein can be applied within processes, such as ALD, with a low back-pressure of about 0.1 to 10 Torr, or in some implementations, 0.1 to 5 Torr, or in some implementations, 0.1 to 2 Torr. The back-pressure is defined as the difference between the pressure in the reaction space and the pressure inside the nozzle.

The composite nozzle 140 and outlet 160 can be positioned relative to each other to provide different flow paths of fluid across the substrate 130 when the substrate 130 is positioned on the substrate support 120. For example, the composite nozzle 140 can extend along an axis of elongation 900, such as along the side 111 of the reaction chamber 110 as shown. The axis of elongation 900 can be approximately parallel with an edge of the substrate 130 positioned on the substrate support 120. The axis of elongation 900 can be approximately horizontal. The composite nozzle 140 and the axis of elongation 900 can be positioned within the reaction chamber 110 to extend along the length or width of a substrate positioned on the substrate support 120.

Referring still to FIG. 3, the outlet 160 can be positioned such that flow through the reaction chamber 110 from the composite nozzle 140 to the outlet 160 can be approximately parallel to a major surface (such as the upper and/or lower surface) of the substrate 130, when the substrate 130 is positioned on the substrate support 120. Such flow that is parallel to a major surface of the substrate 130 can also be defined as “horizontal flow” or “cross-flow,” such that the reaction chamber 110 can be defined as a “horizontal flow” or “cross-flow” reaction chamber, or reactor 100 can be defined as a “horizontal flow” reactor or “cross-flow” reactor.

It will be understood that various positioning and quantities of composite nozzle(s) and outlet(s) can be implemented, for example, to achieve the horizontal or cross-flow within the reaction chambers described herein. Continuing to refer to FIG. 3, the composite nozzle 140 is shown as positioned on the side 111 of the reaction chamber 110 that is opposite to that of side 113, on which the outlet 160 is positioned. One or more additional composite nozzles and outlets (not shown) can be implemented, such that the composite nozzle 140 and outlet 160 shown in FIG. 3 can form a first composite nozzle and a first outlet. For example, a second composite nozzle can be positioned on a second side of the reaction chamber adjacent to the first composite nozzle (such as one of side 112 or 114 shown in FIG. 3), with a second, corresponding outlet on the opposite side of the reaction chamber relative to the second composite nozzle (such as the other of side 112 and 114). In some implementations, a second composite nozzle can be positioned on the same side of the reaction chamber as the first outlet (such as side 113 shown in FIG. 3), with a corresponding second outlet positioned on the opposite side of the reaction chamber as the second composite nozzle, or the same side as the first composite nozzle (such as side 111 shown in FIG. 3). In some implementations, such as that shown in FIG. 5, first and second composite nozzles can be configured to extend along a common side of the reaction chamber.

Referring to FIGS. 3 and 4, the composite nozzle 140 can be configured in any of a number of different ways suitable to provide fluid communication between the reactant source 150 and the inner volume of the reaction chamber 110. The composite nozzle 140 can include any materials suitable for exposure to the process within reaction chamber 110, such as those materials described generally herein for reaction chamber 110, or other suitable materials. As described above, the composite nozzle 140 can include two or more sections or nozzles, such as first nozzle 140A and second nozzle 140B (best seen from the elevational view of FIG. 4), each in communication with the reactant source 150, to communicate the reactant from reactant source 150 to reaction chamber 110. Each of nozzles 140A and 140B can include a nozzle body 141 forming an inner plenum or volume 142. The nozzle body 141 and inner volume 142 can be any of a number of different suitable shapes, and can be the same or different shape with respect to each other. The nozzle body 141 and inner volume 142 can form a nozzle tube of an approximately circular, square, or other cross-sectional shape. The nozzle body 141 can include a first end 141A, and a second, opposite end 141B.

Nozzles 140A and 140B (obscured by nozzle 140A in the view of FIG. 3) can include an inlet 143A and 143B, respectively, configured to provide fluid communication between the reactant source 150 and the inner volume 142. The inlets 143A and 143B can include an opening, pipe, conduit, fitting, and/or other components suitable to provide this communication between the reactant source 150 and the inner volume 142 of each of nozzles 140A and 140B, respectively. In the illustrated implementation, the inlets 143A and 143B are connected to opposite end portions of the respective nozzle bodies 141. For example, inlet 143A can be connected to the first end portion 141A of body 141 of nozzle 140A, and inlet 143B can be connected to the second, opposite, end portion 141B of body 141 of nozzle 140B. The inlets 143A and 143B can be oriented at different orientations relative to the axis of elongation 900 for the composite nozzle 140 and the bodies 141 of nozzles 140A and 140B. For example, the inlets 143A and 143B can be oriented approximately parallel to (e.g., aligned with) the axis of elongation 900, as shown, or at an angle (e.g., approximately orthogonal) to the axis of elongation 900. The inlets 143A, 143B can extend through and be connected to various portions of the respective nozzle bodies 141, such as any of the sides, top or bottom, to provide fluid communication with the respective inner volume 142. In some implementations, the inlets 143A and 143B can extend through a portion of the reaction chamber 110, such as sides 112 and 114, respectively, as shown, to communicate with the reactant source 150. Alternatively, the inlets 143A and 143B can be connected to a conduit or other fluid communication structure that extends through a portion of the reaction chamber 110.

The nozzles 140A and 140B can provide fluid communication between inlets 143A and 143B, respectively, and reaction chamber 110 in any of a number of different ways. In some implementations, nozzles 140A and 140B can each include a plurality of holes spaced along the axis of elongation 900. For example, nozzle 140A can include a plurality of holes 145a-145j (FIGS. 3 and 4), and nozzle 140B can include a plurality of holes 146a-146j (FIG. 4). Although illustrated aligned, in some implementations, holes 145a-145j of nozzle 140A and holes 146a-146j of nozzle 140B may be staggered with respect to each other and the axis of elongation 900. The holes can provide fluid communication between the inner volume 142 of the nozzle body 141 and the reaction chamber 110, and can have any suitable shape for providing such functionality. For example, the holes can have a curved cross-sectional shape, such as a round cross-sectional shape, or can include flat portions, for example, to form a slot. It will be understood that the number of holes implemented within any of the nozzles described herein can be varied, and that the number of holes shown is for illustrative purposes only. For example, for a large, rectangular format substrate with dimensions of approximately 730 mm×920 mm, the number of holes in composite nozzle 140 may range between approximately 15 and 125, with a diameter that may range between approximately 0.2 mm and 1.25 mm. It will also be understood that the holes can be variably spaced or equidistantly spaced with respect to each other along the axis of elongation 900. It will also be understood that the size of the holes can be approximately equal, or vary, with respect to each other along the axis of elongation 900. For example, the plurality of holes of one or more of the nozzles can be approximately equally spaced, and in some implementations, also approximately equal size, as shown, along the axis of elongation with respect to each other. In some implementations, the holes may have unequal size with respect to each other (for example, increasing cross-sectional area with increasing distance from the inlet) along the axis of elongation, to improve flow uniformity. In some implementations, the holes may have unequal spacing with respect to each other (for example, decreasing spacing with increasing distance from the inlet) along the axis of elongation, to improve flow uniformity. Other variations of the hole size and/or hole spacing along the axis of elongation are possible for optimizing the flow uniformity of the composite nozzle.

Referring to FIGS. 3 and 4, a pressure drop can occur within nozzles 140A, 140B with increasing distance from inlets 143A and 143B, respectively. For example, a pressure drop can occur within nozzle 140A with increasing distance in a direction indicated by arrow 901A from inlet 143A. Similarly, a pressure drop can occur within nozzle 140B with increasing distance in a direction shown by arrow 901B from inlet 143B. For each individual nozzle 140A or 140B, this can produce non-uniform flow rates in a gradient across the holes 145a-145j or 146a-146j, with volumetric flow rates dropping with increasing distance from their respective inlets 143A or 143B. However, the overall flow rates seen across the width of the composite nozzle 140 and substrate 130 will equal the sum of the flow from both nozzles 140A and 140B. Positioning the inlet 143A at the first end 141A of the nozzle body 141 of the first nozzle 140A, and the inlet 143B of the second nozzle 140B at the second, opposite, end 141B of the nozzle body 141 of the second nozzle 140B can compensate for the individual effects of the pressure drop in each nozzle 140A, 140B, namely opposite gradients of volumetric flow rates, and provide a combined, overall flow distribution of reactant from nozzle 140 (shown schematically by direction arrows 902 in FIG. 3) with improved uniformity compared to the uniformity of one of the first nozzle 140A or second nozzle 140B alone.

FIG. 5 is a cross-sectional view of a reactor for processing a substrate, showing a front elevational view of two stacked composite nozzles, in accordance with an implementation. A reactor 200 can include a reaction chamber 210, and many of the features described herein generally for a reactor for processing substrates. For example, reactor 200 can include the composite nozzle 140 in communication with the reactant source 150, similar to reactor 100 in FIGS. 3 and 4. The reactor 200 can include two composite nozzles 140 and 240 in communication with different reactants. For example, the reactor 200 can include a second composite nozzle 240 in communication with a second reactant source 250, providing a different reactant from that of the first reactant source 150. It will be understood that two or more composite nozzles can be implemented within the various reactors described herein, unless stated otherwise. The second composite nozzle 240 can be similar to the first composite nozzle 140. For example, the second composite nozzle 240 can include a first nozzle 240A and second nozzle 240B, each with a body 241, and a plurality of holes 245a-245i and 246a-246i, respectively, and inlets 243A and 243B, respectively, that are similar to first nozzle 140A, second nozzle 140B, body 141, and holes 145a-145j and 146a-146j, respectively, of the first composite nozzle 140. The inlet 243A can be positioned at a first end 241A of the nozzle body 241 of the first nozzle 240A, and the inlet 243B of the second nozzle 240B can be positioned at a second, opposite end 241B of the nozzle body 241 of the second nozzle 240B. Thus, nozzle 240 can compensate for the individual effects of the pressure drop in individual nozzles 240A and 240B thereof, and provide a combined, overall flow distribution of a second reactant from nozzle 240 with improved uniformity, similar to the pressure drop compensation for the first reactant from nozzle 140. Including two or more composite nozzles, such as composite nozzles 140 and 240, can allow processes to be performed within the reaction chamber 210 that use two reactants where it is desirable to avoid common flow paths before entering the reaction space, such as ALD and/or some CVD processes. For example, the reactor 200 can include nozzle 140 for supplying a metal precursor from reactant source 150, and nozzle 240 for supplying an oxygen precursor from reactant source 250 for ALD of a metal oxide.

The composite nozzles 140 and 240 can be stacked (e.g., vertically) with respect to each other. For example, the composite nozzles 140 and 240 can be stacked with respect to each other, with nozzles 140A and 140B positioned adjacent to each other, and the nozzles 240A and 240B positioned adjacent to each other, as shown in FIG. 5. In other implementations, the composite nozzles 140 and 240 can be stacked with respect to each other, such that nozzles 140A and 240B are positioned adjacent to each other, and the nozzles 240A and 140B are positioned adjacent to each other (e.g., with alternating nozzles from different composite nozzles). The separate composite nozzles can allow a first gas, such as an inert gas or first reactant, to be flowed from one of the two composite nozzles, while a second gas, such as an inert gas or second reactant, is flowed from the other of the two composite nozzles. For ALD typically one composite nozzle flows a reactant while the other composite nozzle flows an inert gas. For example, an inert gas may be flowed from the lower composite nozzle 240 to mix, and thus improve uniformity of distribution, of a reactant flowing from the upper composite nozzle 140 to substrate 130. Moreover, the holes of two or more composite nozzles (or two or more nozzles within a single composite nozzle, or two or more nozzles within two or more separate composite nozzles) that are vertically stacked can be staggered or aligned with respect to each other and the axis of elongation, in various arrangements. For example, the holes 145a-145j and/or 146a-146j of the composite nozzle 140 can be staggered, as shown, with respect to the holes 245a-245i and/or 246a-246i of composite nozzle 240 and the axis of elongation 900. The holes 145a-145j of the composite nozzle 140 can be aligned, as shown, with respect to the holes 146a-146j (also of composite nozzle 140) and axis 900. The holes 245a-245i of the composite nozzle 240 can be aligned, as shown, with respect to the and 246a-246i (also of composite nozzle 240). In some other implementations, not shown, the holes 145a-145j can be staggered with respect to the holes 146a-146j, such that the holes of nozzles 140A and 140B of composite nozzle 140 are staggered with respect to each other. Similarly, the holes 245a-245i can be staggered with respect to the holes 246a-246i, such that the holes of nozzles 240A and 240B of the composite nozzle 240 are staggered with respect to each other. In some implementations, whether the holes of two nozzles forming a composite nozzle are staggered with respect to each other or not, when two composite nozzles are stacked one atop the other, the holes of the two adjacent nozzles, each of the two adjacent nozzles being part of a different composite nozzle, can be staggered with respect to each other. Staggering the holes can help prevent vortices of reactants leaving the composite nozzles, which can cause increased, unwanted particle deposition. Whether or not staggered, the stacked arrangements provides particular uniformity benefits for the reactant flowed from the upper composite nozzle 140, which can ride on top of the inert gas flow below and thus better diffuse laterally before encountering the substrate. Such a configuration can provide increased improvements in uniformity of reactant distribution for a first reactant such as H₂O, flowed from the upper composite nozzle 140, which would otherwise have decreased uniformity of distribution relative to a second reactant flowed from composite nozzle 240 (between composite nozzle 140 and the substrate), such as TMA. In the implementation shown in FIG. 5, the holes of composite nozzles 140 and 240 are shown offset or staggered (e.g., vertically) with respect to each other and axis 900. The composite nozzles (and their respective separate nozzles) described herein, can contact each other, or be separated by a gap or distance, and still be considered “separate” because their nozzle walls prevent direct communication between the inner volumes of the various nozzles.

In some implementations, two or more composite nozzles can be positioned on a common side of the reaction chamber 210 with respect to each other, such as the stacked composite nozzles 140 and 240 shown in FIG. 5. In some implementations, the composite nozzles 140 and 240 can be positioned on different sides of the reaction chamber 210 with respect to each other, such as two adjacent sides, or two opposing sides.

Implementations of the nozzles described herein can include a nozzle outlet positioned at the end of each nozzle body that is opposite to the nozzle inlet for that nozzle body. Each nozzle outlet can be in selective communication with a vacuum supply. A separate nozzle outlet connected directly to the nozzle body can decrease purge time of the nozzle relative to a reactor that purges the nozzle through its openings to the reaction space. A separate nozzle outlet for use during purging can also reduce the likelihood of residual reactant remaining in the nozzle, for example, after a reactant pulse, which can cause particle contamination as described elsewhere herein. Continuing to refer to FIG. 5, nozzles 140A and 140B can have nozzle outlets 171A and 171B, respectively, connected to ends 141B and 141A, respectively. The nozzle outlets 171A and 171B can be connected to a vacuum supply 170. Similar outlets 271A and 271B can be provided for nozzles 240A and 240B opposite from the ends at which the inlets 243A and 243B are provided. Similar implementations can be employed within the other nozzles described herein.

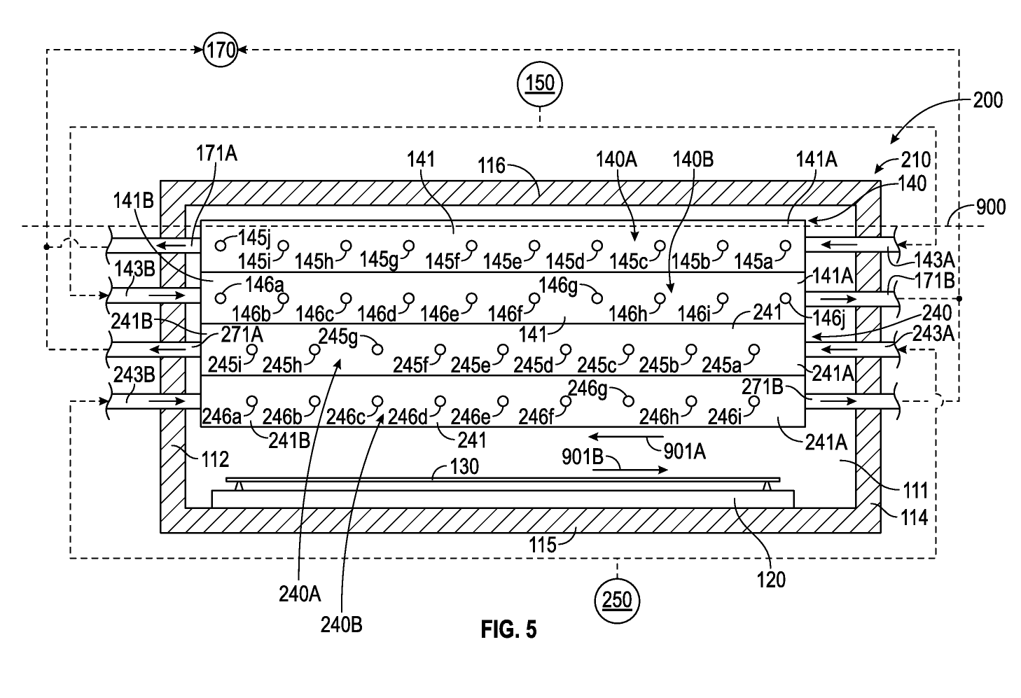

FIG. 6 is an example of a system block diagram illustrating the reactor 100 including a reaction chamber and a control system, in accordance with an implementation. Reactor 100 can include a control system or controller 1000 to control various features of, or methods provided by, one or more other components of the reactor 100, such as the reaction chamber 110. The reactor 100 can be controlled electronically, but can include other types of control sub-systems or components such as pneumatic or hydraulic. The control system 1000 can include any of a number of configurations, and can include any of a variety of controllers, user interfaces, buttons, switches, circuits, and the like. The control system 1000 can control any of the number of components of the reaction chamber 110. For example, the control system 1000 can control the flow of gas into or from the reaction chamber, or within portions of the reaction chamber. The control system 1000 can be configured to control different reactants into the reaction chamber. For example, control system 1000 can control valves to alternatingly switch between different reactant sources and outlets (if multiple outlets are positioned on different sides), and vacuum pump(s) to control system pressure, possible responsive to a feedback loop from a pressure sensor. The control system 1000 can control the robotics implementing movement of the substrate to and from the reaction chamber 110. In some implementations, the control system 1000 can be in communication with, and/or can be a part of, a control system and/or network within a facility for fabricating electromechanical system devices and/or integrated circuit devices.

In some implementations, the control system 1000 can be hard-wired to the components or sub-components of reactor 100, or can be configured to control the components or sub-components wirelessly. The control system 1000 can be in communication with a network 1300. The control system 1000 can be attached to a portion of reactor 100 (for example, reaction chamber 110) or can be separate from such a portion of reactor 100. In some implementations, the control system 1000 can be configured to control various aspects of the reactor 100 remotely (e.g., through a telecommunication system, wirelessly, and/or an additional control system that sends a control signal to control system 1000, etc.), that allow remote interaction with and control one or more reactors 100 and their components, for example, from a central station. The control system 1000 can include a processor 1100, which can be a central processing unit (CPU), a microcontroller, or a logic unit. In some implementations, the control system 1000 can include a memory 1200, which can be local to the remainder of control system 1000, or can be located remote from the remainder of control system 1000 (for example, through cloud computing methods). The memory 1200 can include programming for conducting processing on substrates in sequence, including the method of FIG. 8, described below.

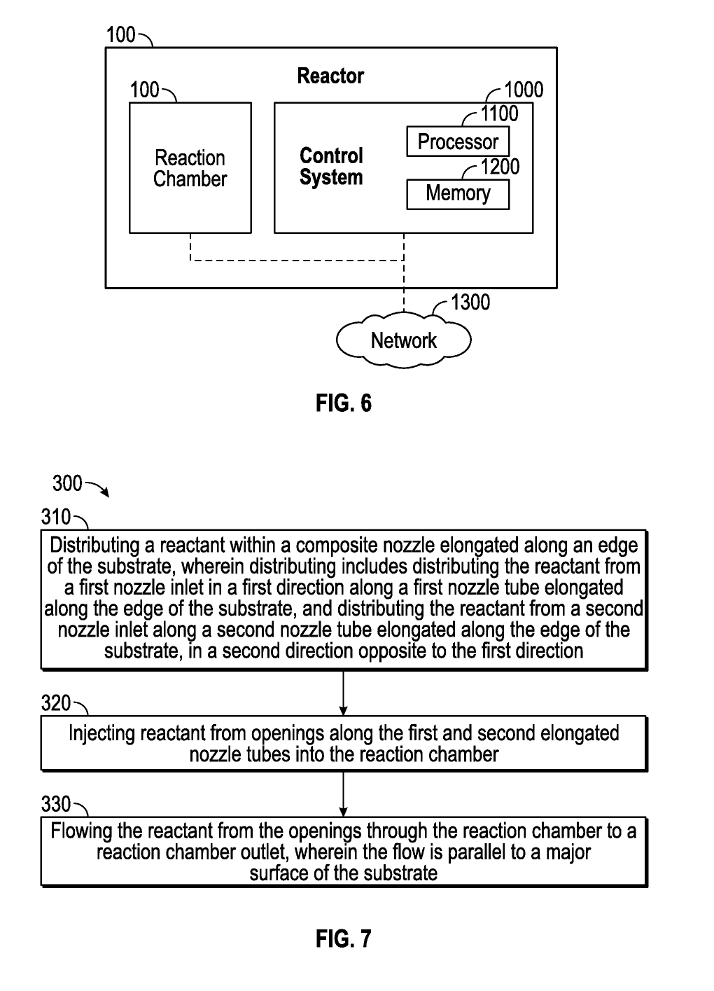

FIG. 7 is an example of a flow diagram illustrating a method of processing a substrate, in accordance with an implementation. The method 300 can include distributing a reactant within a composite nozzle elongated along an edge of the substrate at block 310. Distributing can include distributing the reactant from a first nozzle inlet in a first direction along a first nozzle tube elongated along the edge of the substrate. Distributing can include distributing the reactant from a second nozzle inlet along a second nozzle tube elongated along the edge of the substrate, in a second direction opposite to the first direction. At block 320, the method can include injecting reactant from openings along the first and second elongated nozzle tubes into the reaction chamber. At block 330, the method can include flowing the reactant from the openings through the reaction chamber to a reaction chamber outlet, wherein the flow is parallel to a major surface of the substrate.

In some implementations, injecting reactant includes presenting a back-pressure of less than 5 Torr to gases. In some implementations, the same reactant or reactant mixture is simultaneously supplied to the first and second nozzle inlets. In some implementations, the method includes repeating the method 300 within the single substrate reaction chamber, with a separate reactant, within a separate composite nozzle with separate nozzle inlets and separate nozzle tubes, with separate openings. In some implementations, flowing the reactant from the openings includes flowing reactant from adjacent first and second nozzle tubes corresponding to the same composite nozzle. In some implementations, distributing the reactant within the nozzle and distributing the separate reactant within the separate nozzle occurs sequentially with respect to each other and includes alternatingly switching between flowing the reactant and flowing the separate reactant into the reaction chamber. In some implementations, the method includes performing an ALD process. In some implementations, the method further includes removing reactant from the nozzle after distributing the reactant within the nozzle and prior to distributing the separate reactant within the second nozzle. In some implementations, distributing the reactant from the nozzle inlet and distributing the separate reactant from the separate nozzle inlet includes distributing from a common edge of the substrate. In some implementations, flowing the reactant includes flowing the reactant to the reaction chamber outlet positioned on an opposite side of the substrate relative to the common edge of the substrate. In some implementations, the method further includes removing reactant from one of the first nozzle tube or the second nozzle tube, or both, from a nozzle outlet positioned at an end of the nozzle tube opposite to the nozzle inlet. In some implementations, the reaction chamber is configured to process rectangular substrates having an area greater than the area of rectangular substrate with dimensions of about 700 mm by about 900 mm.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various methods described in connection with the implementations disclosed herein may be implemented manually or through automation controlled by electronic hardware, computer software, or combinations of both. Whether such functionality is implemented in hardware or software depends upon the particular application and design constraints imposed on the overall system.

For automated control, the hardware and data processing apparatus used to implement the functionability described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper,” “lower,” “horizontal,” “vertical,” “up,” “down,” “top,” “front,” bottom,” and “side” are sometimes used for ease and convenience of describing the figures, components, and views, and indicate relative positions corresponding to the orientation of the figure on a properly oriented page, and may not reflect the proper orientation of, for example, nozzles relative to the workpiece and/or outlet in some implementations. These terms should not limit the invention to any absolute orientations, for example, with respect to ground; the entire reactors described herein, could be oriented on its side, upside down, etc.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A reactor for processing a substrate, including:
a reaction chamber configured to process a single substrate;
a substrate support configured to support a single substrate within the reaction chamber;
a composite nozzle extending along a side of the reaction chamber, the composite nozzle including a first nozzle and a second nozzle separate from and positioned parallel the first nozzle, wherein each nozzle includes:
a nozzle body forming an inner volume, the nozzle body extending along an axis of elongation;
an inlet providing fluid communication between at least one source of a common reactant species and the inner volume; and
a plurality of holes spaced along the axis of elongation of the nozzle body, the holes providing fluid communication between the inner volume of the nozzle body and the reaction chamber; and
a reaction chamber outlet positioned and configured to allow flow from the composite nozzle through the reaction chamber to the reaction chamber outlet, wherein the flow is parallel to a major surface of the substrate;
wherein the inlet of the first nozzle is positioned at a first end of the nozzle body of the first nozzle, and the inlet of the second nozzle is positioned at a second end of the nozzle body of the second nozzle, where the second end is opposite to the first end of the nozzle body of the first nozzle.

2. The reactor of claim 1, wherein the composite nozzle is configured to present a back-pressure of less than 5 Torr to gases.

3. The reactor of claim 1, wherein the reactor includes separate ones of the composite nozzle.

4. The reactor of claim 3, wherein at least two of the composite nozzles are stacked vertically adjacent to each other.

5. The reactor of claim 3, wherein the reactor is configured for atomic layer deposition (ALD), and at least one of the composite nozzles is in communication with at least one source of a first ALD reactant species, and at least another of the composite nozzles is in communication with at least one source of a second ALD reactant species.

6. The reactor of claim 5, wherein the first reactant species includes a metal source precursor, and the second reactant species includes an oxygen precursor.

7. The reactor of claim 5, wherein the first reactant species is delivered from a common first reactant source and the second reactant species is delivered from a common second reactant source, and further including a control system for alternatingly switching between the first and second reactant sources.

8. The reactor of claim 3, wherein at least two of the composite nozzles extend along a common side of the reaction chamber.

9. The reactor of claim 8, wherein the common side of the reaction chamber is positioned on an opposite side of the substrate support relative to the reaction chamber outlet.

10. The reactor of claim 1, further including a nozzle outlet positioned at each end of each nozzle body that is opposite to the nozzle inlet for the corresponding nozzle body, wherein each nozzle outlet is in communication with a vacuum supply.

11. The reactor of claim 1, wherein the reaction chamber is configured to process rectangular substrates having an area greater than the area of rectangular substrate with dimensions of about 700 mm by about 900 mm.

12. The reactor of claim 2, wherein the plurality of holes of at least one of the nozzles are approximately equal size, and approximately equally spaced along the axis of elongation, with respect to each other.

13. A reactor for processing a substrate, including:
a reaction chamber configured to process a single substrate having a surface;
a means for supporting a substrate within the reaction chamber; and
a means for introducing a reactant into the reaction chamber parallel to the substrate surface, the reactant introducing means including:
a first means for injecting the reactant into the reaction chamber with a first decreasing gradient of volumetric flow rates extending parallel to an edge of the substrate; and
a second means for injecting the reactant into the reaction chamber with a second decreasing gradient of volumetric flow rates extending parallel to the edge of the substrate and opposite to the first gradient, to compensate for the first gradient.

14. The reactor of claim 13, wherein the first reactant injecting means includes a first nozzle tube and a first inlet positioned at a first end of the first nozzle tube, and the second reactant injecting means includes a second nozzle tube and a second inlet positioned at a second end of the second nozzle tube that is opposite to the first end of the first nozzle tube, the second nozzle tube approximately parallel to the first nozzle tube.

15. The reactor of claim 14, wherein the reactor includes at least two reactant introducing means stacked vertically adjacent with respect to each other.

16. The reactor of claim 14, further including a nozzle outlet positioned at second ends of each nozzle tube, the second ends being opposite the first ends, wherein each nozzle outlet is in communication with a vacuum supply.

17. The reactor of claim 13, wherein the reactant introducing means is configured to present a back-pressure of less than 5 Torr to gases.

18. The reactor of claim 13, wherein the reactor includes separate ones of the reactant introducing means.

19. The reactor of claim 18, wherein the reactor is configured for atomic layer deposition (ALD), and wherein at least one of the reactant introducing means is in communication with a first ALD reactant source, and at least another of the reactant introducing means is in communication with a second, different ALD reactant source.

20. The reactor of claim 19, further including a control system for alternatingly switching between the different reactant sources.

21. The reactor of claim 18, wherein the separate ones of the reactant introducing means extend along a common side of the reaction chamber.

22. The reactor of claim 13, wherein the reaction chamber is configured to process rectangular substrates having an area greater than the area of rectangular substrate with dimensions of about 700 mm by about 900 mm.

23. A method of processing a substrate in a single substrate reaction chamber, including:
distributing a reactant within a composite nozzle elongated along an edge of the substrate, wherein distributing includes:
distributing the reactant from a first nozzle inlet in a first direction along a first nozzle tube elongated along the edge of the substrate; and
distributing the reactant from a second nozzle inlet along a second nozzle tube elongated along the edge of the substrate, in a second direction opposite to the first direction;
injecting reactant from openings along the first and second elongated nozzle tubes into the reaction chamber; and
flowing the reactant from the openings through the reaction chamber to a reaction chamber outlet, wherein the flow is parallel to a major surface of the substrate.

24. The method of claim 23, wherein injecting reactant includes presenting a back-pressure of less than 5 Torr to gases.

25. A method including repeating the method of claim 23 within the single substrate reaction chamber, with a separate reactant, within a separate composite nozzle with separate nozzle inlets and separate nozzle tubes, with separate openings.

26. The method of claim 25, wherein flowing the reactant from the openings includes flowing reactant from adjacent first and second nozzle tubes corresponding to the same composite nozzle.

27. The method of claim 25, wherein distributing the reactant within the composite nozzle and distributing the separate reactant within the separate composite nozzle occurs sequentially with respect to each other and includes alternatingly switching between flowing the reactant and flowing the separate reactant into the reaction chamber.

28. The method of claim 27, wherein the method includes performing an ALD process.

29. The method of claim 28, further including removing reactant from the nozzle after distributing the reactant within the nozzle and prior to distributing the separate reactant within the second nozzle.

30. The method of claim 25, wherein distributing the reactant from the nozzle inlet and distributing the separate reactant from the separate nozzle inlet includes distributing from a common edge of the substrate.
